(19) United States
(12) Patent Application Publication
(10) Pub. No.: US 2023/0009977 A1
(43) Pub. Date: Jan. 12, 2023

(54) SOURCE/DRAIN CONTACTS BETWEEN TRANSISTOR GATES WITH ABBREVIATED INNER SPACERS FOR IMPROVED CONTACT AREA AND RELATED METHOD OF FABRICATION

(71) Applicant: QUALCOMM Incorporated, San Diego, CA (US)

(72) Inventors: Junjing Bao, San Diego, CA (US); Haining Yang, San Diego, CA (US); Youseok Suh, San Diego, CA (US)

(21) Appl. No.: 17/371,701

(22) Filed: Jul. 9, 2021

(51) Int. Cl. H01L 29/66; H01L 29/78; H01L 27/088; H01L 21/8234; H01L 29/08

(52) U.S. Cl. CPC H01L 29/6656; H01L 29/7851; H01L 27/0886; H01L 21/823418; H01L 21/823468; H01L 29/0843

(57) ABSTRACT

Source/drain contacts between transistor gates with abbreviated inner spacers for improved contact area are disclosed. Related methods of fabricating source/drain contacts and abbreviated inner spacers are also disclosed. Inner spacers formed on sidewalls of the gates of adjacent transistors are abbreviated to reduce an amount of the space the inner spacers occupy on the source/drain region, increasing a critical dimension of the source/drain contact. Abbreviated inner spacers extend from a top of the gate over a portion of the sidewalls to provide leakage current protection but do not fully extend to the semiconductor substrate. As a result, the critical dimension of the source/drain contact can extend from a sidewall on a first gate to a sidewall on a second gate. A source/drain contact formed between gates with abbreviated inner spacers has a greater surface area in contact with the source/drain region providing decreased contact resistance.

### BACKGROUND

### I. Field of the Disclosure

The field of the disclosure relates generally to transistor terminal contacts and more particularly to source/drain contacts disposed between gates on a semiconductor substrate.

### 1. BACKGROUND

Integrated circuits (ICs) include transistors efficiently organized on a semiconductor substrate to minimize IC area. The dimensions of transistors trend toward becoming smaller with each new generation of technology such that more transistors can fit in a given area of an IC or a given number of transistors can fit in a smaller area. New challenges arise as the dimensions of transistor structures and the distance between adjacent transistors become smaller.

Transistors may be formed in a diffusion region of a semiconductor substrate. Transistors include gates formed on channels in the diffusion region. Sources and/or drains (“source/drains”) of the transistors are disposed in the diffusion region between the gates of adjacent transistors. Contacts may be formed on the source/drains in the diffusion regions to connect the source/drain in a circuit. However, the widths of the source/drains become narrower as the space between gates gets smaller. Exacerbating this issue is that the space in which the contact can be formed is also occupied by insulating sidewalls and inner spacers that are disposed on the sides of both gates. The sidewalls insulate the gates from the contact and the inner spacers reduce leakage currents through the sidewalls. The remaining distance between the inner spacers for forming the contact to the source/drain is limited. As that space between gates narrows, the width of the contact on the source/drain decreases, which increases contact resistance and affects performance and power consumption of the IC.

### SUMMARY OF THE DISCLOSURE

Aspects disclosed herein include source/drain contacts between transistor gates with abbreviated inner spacers for improved contact area. Related methods of fabricating source/drain contacts and abbreviated inner spacers are also disclosed. Gates of adjacent transistors on a semiconductor substrate are separated at a gate pitch. A source/drain region shared by the transistors is located in a space between the gates. This space is partially taken up by the thickness of sidewalls on each of the gates and by inner spacers disposed on each of the sidewalls. The inner spacers reduce leakage currents between the gates and a source/drain contact that is formed on the source/drain region. A width of such space decreases as the gate pitches of new technologies decrease, which reduces a critical dimension of an area in which a source/drain contact can be formed. In an exemplary aspect, inner spacers formed on the sidewalls of the gates are abbreviated to reduce an amount of the space the inner spacers occupy and increase a critical dimension of the source/drain contact. For example, abbreviated inner spacers extend from a top of the gate over a portion of the sidewall to provide leakage current protection but do not extend down a full height of the sidewall to contact a semiconductor substrate. In this manner as an example, the critical dimension of the source/drain contact disposed on the semiconductor substrate is measured from a sidewall on a first gate to a sidewall on a second gate. A source/drain contact formed between gates with abbreviated inner spacers has a greater surface area in contact with the source/drain region providing decreased contact resistance.

In an exemplary aspect, an integrated circuit (IC) comprising a first transistor and a second transistor on a semiconductor substrate is disclosed herein. The first transistor comprises a first gate on a first channel region and the first gate comprises a top and a first side. The second transistor comprises a second gate on a second channel region and the second gate comprises a top and a second side. The IC further comprises a source/drain region between the first gate and the second gate, a first sidewall disposed on the first side of the first gate and a second sidewall disposed on the second side of the second gate. The IC further comprises a first inner spacer disposed on the first sidewall and a second inner spacer disposed on the second sidewall. The IC comprises a source/drain contact disposed on the source/drain region, the source/drain contact in direct contact with the first inner spacer, the second inner spacer, the first sidewall, and the second sidewall.

In another exemplary aspect, a method of fabricating a source/drain contact is disclosed. The method includes forming a first sidewall on a first side of a first gate of a first transistor and a second sidewall on a second side of a second gate of a second transistor. The method includes forming a first inner spacer on the first sidewall and a second inner spacer on the second sidewall. The method further includes forming a source/drain contact on a source/drain region of the first transistor and the second transistor between the first gate and the second gate, the source/drain contact in direct contact with the first inner spacer, the second inner spacer, the first sidewall, and the second sidewall.

### BRIEF DESCRIPTION OF THE FIGURES

FIG. 1A is an illustration of a plan view of a portion of a semiconductor substrate including conventional contacts disposed on a source/drain region between gates in a diffusion region of a semiconductor substrate of an integrated circuit (IC);

FIG. 1B is an illustration of a cross-sectional side view of a contact in FIG. 1A disposed between gates and including sidewalls and full inner spacers as seen from an end view of the gates:

FIG. 1C is an illustration of a cross-sectional side view of the contact in FIG. 1A including inner spacers disposed on the sidewalls and extending from a top of the gate to a diffusion region of a semiconductor substrate as seen from a cross-sectional view of a gate;

FIG. 2A is an illustration of a plan view of an exemplary contact with an increased critical dimension by employing abbreviated inner spacers on gates on a semiconductor substrate of an IC:

FIG. 2B is an illustration of a cross-sectional side view of the contact in FIG. 2A with abbreviated inner spacers for increased critical dimension between gates on the diffusion region of the semiconductor substrate from an end view of the gates;

FIG. 2C is an illustration of a cross-sectional side view of the contact in FIG. 2A with abbreviated inner spacers for increased critical dimension disposed on a diffusion region of a semiconductor substrate including fins from an end view of the fins;

FIGS. 3A and 3B are cross-sectional side views orthogonal to each other in a first stage of fabrication of the source/drain contact and abbreviated inner spacers in FIGS. 2A-2C;

FIGS. 4A and 4B are cross-sectional side views orthogonal to each other in a second stage of fabrication of the source/drain contact and abbreviated inner spacers in FIGS. 2A-2C;

FIGS. 5A and 5B are cross-sectional side views orthogonal to each other in a third stage of fabrication of the source/drain contact and abbreviated inner spacers in FIGS. 2A-2C;

FIGS. 6A and 6B are cross-sectional side views orthogonal to each other in a fourth stage of fabrication of the source/drain contact and abbreviated inner spacers in FIGS. 2A-2C;

FIGS. 7A and 7B are cross-sectional side views orthogonal to each other in a fifth stage of fabrication of the source/drain contact and abbreviated inner spacers in FIGS. 2A-2C;

FIGS. 8A and 8B are cross-sectional side views orthogonal to each other in a sixth stage of fabrication of the source/drain contact and abbreviated inner spacers in FIGS. 2A-2C;

FIG. 9 is a flow chart illustrating a method of fabricating the source/drain contact and abbreviated inner spacers in FIGS. 2A-2C and 8A-8B:

FIG. 10 is a block diagram of an exemplary wireless communications device that includes a radio frequency (RF) module including the IC dies including transistors with source/drain contacts and abbreviated inner spacers for greater critical dimension between gates as illustrated in FIGS. 2A-2C and 8A-8B; and

FIG. 11 is a block diagram of an exemplary processor-based system including exemplary IC dies including transistors with source/drain contacts and abbreviated inner spacers for greater critical dimension between gates as illustrated in FIGS. 2A-2C and 8A-8B, and according to any of the aspects disclosed herein.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include source/drain contacts between transistor gates with abbreviated inner spacers for improved contact area. Related methods of fabricating source/drain contacts and abbreviated inner spacers are also disclosed. Gates of adjacent transistors on a semiconductor substrate are separated at a gate pitch. A source/drain region shared by the transistors is located in a space between the gates. This space is partially taken up by the thickness of sidewalls on each of the gates and by inner spacers disposed on each of the sidewalls. The inner spacers reduce leakage currents between the gates and a source/drain contact that is formed on the source/drain region. A width of such space decreases as the gate pitches of new technologies decrease, which reduces a critical dimension of an area in which a source/drain contact can be formed. In an exemplary aspect, inner spacers formed on the sidewalls of the gates are abbreviated to reduce an amount of the space the inner spacers occupy and increase a critical dimension of the source/drain contact. For example, abbreviated inner spacers extend from a top of the gate over a portion of the sidewall to provide leakage current protection but do not extend down a full height of the sidewall to contact a semiconductor substrate. In this manner as an example, the critical dimension of the source/drain contact disposed on the semiconductor substrate is measured from a sidewall on a first gate to a sidewall on a second gate. A source/drain contact formed between gates with abbreviated inner spacers has a greater surface area in contact with the source/drain region providing decreased contact resistance.

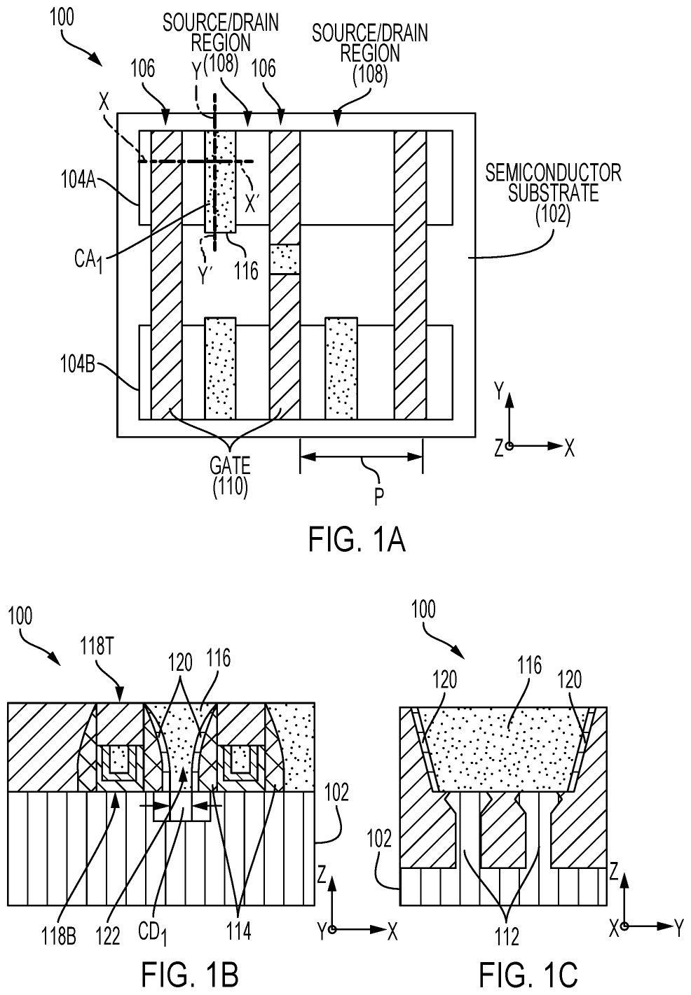

Transistors are formed as close to each other as possible on a semiconductor substrate to maximize area efficiency. A metal-oxide semiconductor (MOS) field-effect transistor (FET)(MOSFET) is a type of transistor frequently used in ICs. Each MOSFET includes a source and a drain that are formed on opposite sides of a channel region. Current flow through the channel region is controlled by a voltage applied to a gate disposed on the channel region, and also by a voltage applied between the source and drain. FIG. 1A is an illustration of a plan view (e.g., top view) of a section 100 of a semiconductor substrate 102 including diffusion regions 104A and 104B in which transistors 106 are formed. FIG. 1B is an illustration of a cross-section taken along a line X-X′ in FIG. 1A. FIG. 1C is an illustration of a cross-section taken along a line Y-Y′ in FIG. 1A. As seen in the plan view of FIG. 1A, the gates 110 are linear structures formed parallel to each other and separated at a gate pitch P on the semiconductor substrate 102. A region 108 of the semiconductor substrate 102 that may be a source or drain of a first transistor 106 on one side of a gate 110 may also be a source or drain of an adjacent second transistor 106. Thus, such regions 108 are also referred to herein as source/drain regions 108.

The semiconductor substrate 102 may include the diffusion regions 104A and 104B formed on a planar surface or one or more fins 112 (see FIG. 1C). The gates 110 are formed on the semiconductor substrate 102 in either a gate-first or gate-last process. In either case, there are sidewalls 114 positioned on either side of each gate 110 to reduce leakage currents between the gate 110 and the source/drain regions 108 on either side of the gate 110. As an example, a source/drain contact 116 is formed on the source/drain region 108 of the semiconductor substrate 102 between two of the gates 110 for connecting the source/drain region 108 to a circuit (not shown). The source/drain contact 116 is separated from the gates 110 by the sidewalls 114. However, due to the methods used to form the sidewalls 114, such as etching, a thickness of a sidewall 114 may be thicker at a bottom 118B of the gate 110 nearer to the semiconductor substrate 102 and thinner at a top 118T of the gate 110. Thus, protection against leakage current provided by the sidewall 114 decreases as the sidewall 114 gets thinner farther from the semiconductor substrate 102.

In the conventional example shown in FIGS. 1A-1C, an inner spacer 120 is formed on each of the sidewalls 114 to provide additional protection against leakage current. As shown in FIG. 1C, the inner spacers 120 extend over the entire sidewall 114 from the top 118T of the gate 110 to the bottom 118B, where the inner spacers 120 are in contact with the semiconductor substrate 102. The inner spacers 120 are formed before the source/drain contact 116. A space 122 between the gates 110 is partially occupied by the sidewalls 114 and the inner spacers 120, such that a critical dimension CD₁ remains in the space 122 for the source/drain contact 116. As the gate pitch P of the gates 110 decreases, the critical dimension CD₁ narrows such that the source/drain contact 116 has a very small area CA₁ of contact with the source/drain region 108. Since a contact resistance R₁ (not shown) between the source/drain contact 116 and the source/drain region 108 is inversely proportional to the area CA₁, the contact resistance R₁ increases as the critical dimension CDⱼ decreases with the gate pitch P.

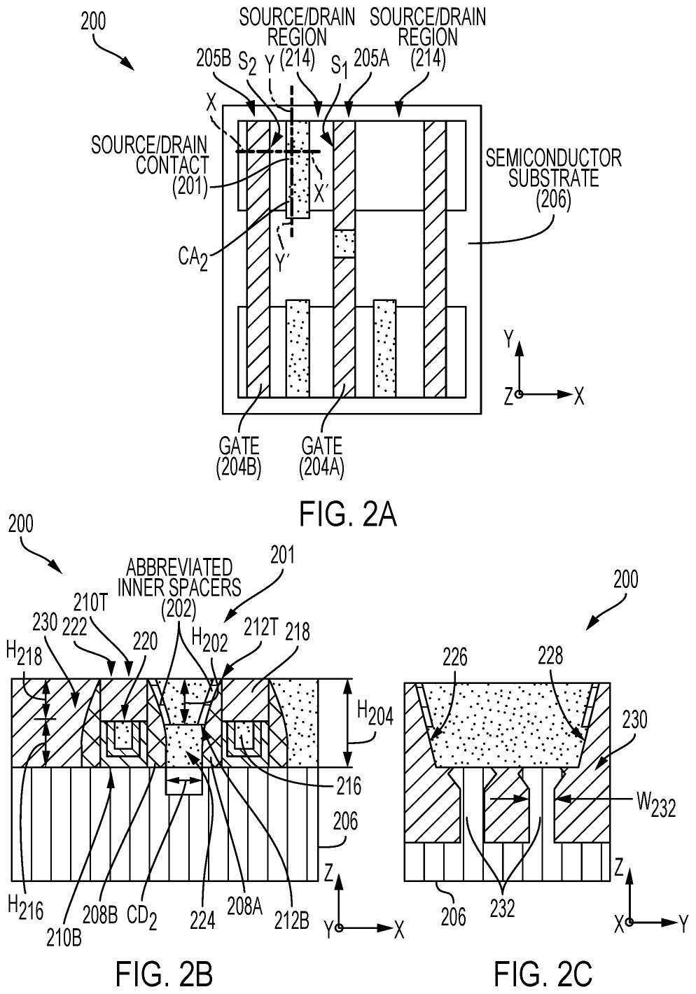

FIGS. 2A-2C include an illustration of an exemplary circuit 200 including a source/drain contact 201 in which a critical dimension CD₂ is increased by employing abbreviated inner spacers 202 between gates 204A and 204B on a semiconductor substrate 206. The gates 204A and 204B may be used to control operation of transistor 205A and transistor 205B, respectively. FIG. 2A is a plan view of the circuit 200 including the source/drain contact 201 and gates 204A and 204B. FIG. 2B is an illustration of a cross-section taken along a line X-X′ in FIG. 2A, and FIG. 2C is an illustration of a cross-section taken along a line Y-Y′ in FIG. 2A.

The semiconductor substrate 206 and gates 204A and 204B correspond to the semiconductor substrate 102 and gates 110 in FIGS. 1A-1C. In addition, FIGS. 2A-2C include a first sidewall 208A disposed on a first side S₁ of the gate 204A and a second sidewall 208B disposed on a second side S₂ of the gate 204B. The sidewalls 208A and 208B may be referred to collectively as the sidewalls 208 and the sidewalls 208 correspond to the sidewalls 114 in FIGS. 1A-1C. The sidewalls 208 may be formed of silicon boron carbon nitride (SiBCN), for example, but are not limited in this regard. As illustrated in FIGS. 2A-2C, however, the source/drain contact 201 and the abbreviated inner spacers 202 differ from the source/drain contact 116 and the inner spacers 120. These differences allow the critical dimension CD₂ in FIG. 2B to be greater than the critical dimension CDₜ in FIG. 1B, which reduces a contact resistance R₂ (not shown) compared to the contact resistance R₁.

The abbreviated inner spacers 202 are abbreviated in the Z-axis (e.g., height) direction, as shown in FIGS. 2B and 2C. As discussed above, the sidewalls 208 are thinner toward a top 210T of the gates 204A and 204B than near a bottom 210B due to methods of forming the sidewalls 208. The effectiveness of the sidewalls 208 in reducing leakage current decreases as the sidewalls 208 get thinner toward the top 210T, so the abbreviated inner spacers 202 are abbreviated in height, primarily covering the sidewalls 208 where they are thinner. Specifically, the gates 204A and 204B have a gate height H₂₀₄, which is a distance from the top 210T to the bottom 210B. The sidewalls 208 extend the gate height H₂₀₄ on the first side S₁ of the gate 204A and on the second side S₂ of the gate 204B. Rather than disposing inner spacers for leakage current protection on the sidewalls 208 over the entire gate height H₂₀₄, including where the sidewalls 208 are thickest near the bottom 210B, the abbreviated inner spacers 202 have a height H₂₀₂ that is less than the gate height H₂₀₄. The abbreviated inner spacers 202 may be a layer of silicon-nitride (SiN) extending from the top 210T of the gates 204A and 204B toward the semiconductor substrate 206. The height H₂₀₂ of the abbreviated inner spacers 202 is a distance in the Z-axis direction from a top edge 212T to a bottom edge 212B of the abbreviated inner spacers 202. The top edges 212T of the abbreviated inner spacers correspond to the tops 210T of the gates 204A and 204B.

In some examples, the height H₂₀₂ of the abbreviated inner spacers 202 is between thirty-five percent (35%) and sixty-five percent (65%) of the gate height H₂₀₄. Thus, between 35% and 65% of the sidewalls 208 closest to the bottom 210B (i.e., where the sidewalls 208 are thickest) may not be covered by the abbreviated inner spacers 202.

In other words, the abbreviated inner spacers 202 do not fully extend to the bottom 210B of the gates 204A and 204B. Therefore, the abbreviated inner spacers 202 are not disposed on a source/drain region 214 between the gates 204A and 204B, which leaves more area available for the source/drain contact 201 to contact the source/drain region 214. In this regard, the source/drain contact 201 extends from the first sidewall 208A on the first side S₁ of the gate 204A to the second sidewall 208B on the second side S₂ of the gate 204B. In some examples, the source/drain contact 201 is in contact with the first sidewall 208A and the second sidewall 208B. In this context, the phrase “in contact with” may refer to indirect contact or direct contact. Indirect contact is where one or more additional layers may be disposed between the source/drain contact 201 and the sidewalls 208. Direct contact means that there are no intervening layers between the source/drain contact 201 and the sidewalls 208. As a result, the critical dimension CD₂ of the source/drain contact 201 is increased and a contact resistance R₂ between the source/drain contact 201 and the source/drain region 214 is reduced.

The height H₂₀₂ of the abbreviated inner spacers 202 may be based on components of the gates 204A and 204B. Each of the gates 204A and 204B may include a metal gate structure 216 and a dielectric cap 218 disposed on a top 220 of the metal gate structure 216. The metal gate structure 216 has a height H₂₁₆ from the top 220 to the semiconductor substrate 206. The dielectric cap 218 has a height H₂₁₈ from a top 222 of the dielectric cap 218 to the top 220 of the metal gate structure 216. In some examples, the top 222 of the dielectric cap 218 is the top 210T of the gate 204A. The heights H₂₀₂, H₂₀₄, H₂₁₆, and H₂₁₈ are distances measured in the Z-axis direction (e.g., vertically) in FIGS. 2A-2C.

The source/drain contact 201 is formed of a contact material 224, which is an electrically conductive material, which may be a metal such as copper, cobalt, or tungsten, for example. The contact material 224 is disposed between the sidewalls 208 and on the sidewalls 208 from the semiconductor substrate 206 to the top edge 212T of the abbreviated inner spacers 202. The contact material 224 is also disposed on the abbreviated inner spacers 202 from the bottom edge 212B to the top edge 212T.

The critical dimension CD₂ of the source/drain contact 201 is measured in a first axis (e.g., X-axis) direction. The source/drain contact 201 also extends in a second axis (e.g., Y-axis) direction (orthogonal to the X-axis direction) on the source/drain region 214 from a first end 226 to a second end 228. As shown in FIG. 2C, the source/drain region 214 of the semiconductor substrate 206 may include fins 232. An area CA₂ of contact between the source/drain region 214 and the source/drain contact 201 on each fin 232 is based on the critical dimension CD₂ and the width dimensions W₂₃₂ of the fins 232 in the Y-axis direction. FIG. 2C also shows that the abbreviated inner spacers 202 are formed on an oxide layer 230 at the ends 226 and 228. The source/drain contact 201 is also in contact with the oxide layer 230 at the ends 226 and 228.

The sidewalls 208 may be silicon boron carbon nitride (SiBCN). The metal gate structure 216 may include a high-K dielectric layer, work function layers (e.g., titanium nitride (TiN)/tantalum nitride (TaN)/titanium aluminum carbide (TiAlC) for N-channel metal-oxide semiconductor (NMOS) transistors or TiN/TaN/TiN/TiAlC for P-channel metal-oxide semiconductor (PMOS) transistors), and a Tungsten (W) metal gate, for example. The dielectric cap 218 may include SiN, for example. The oxide layer 230 may be silicon dioxide (SiO₂). The materials listed herein are non-limiting examples of materials that may be employed in examples disclosed herein.

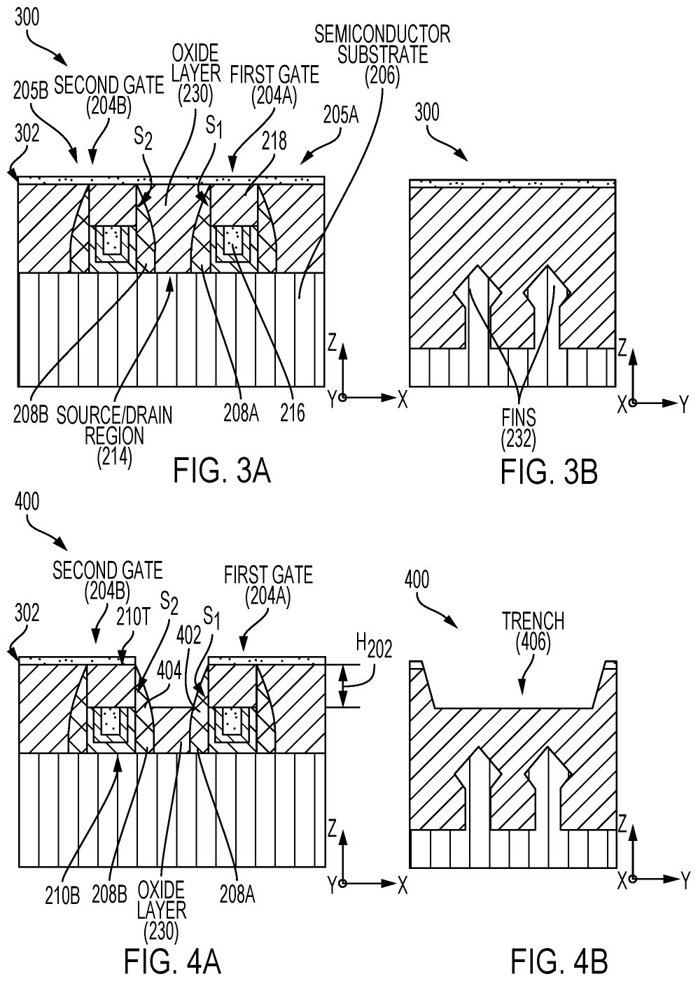

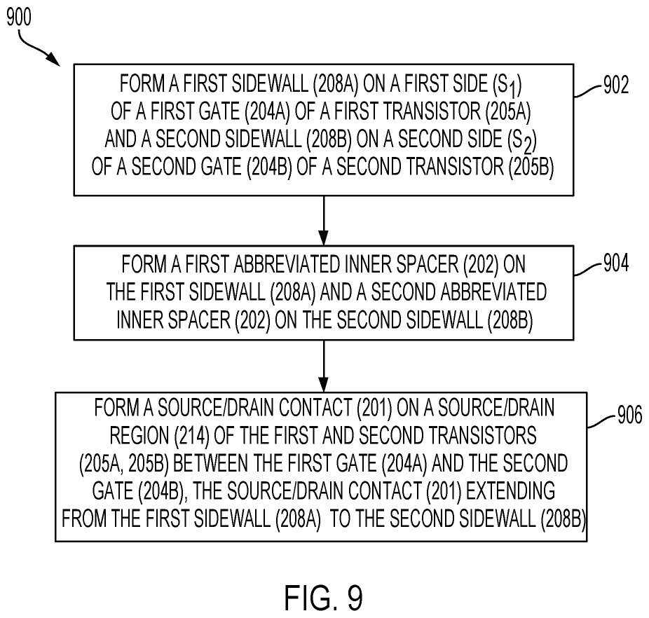

FIGS. 3A and 3B through 8A and 8B illustrate fabrication stages 300-800 of fabricating source/drain contact 201 and abbreviated inner spacers 202 in FIGS. 2A-2C. FIG. 9 is a flowchart of a method 900 of fabricating the source/drain contact 201 and abbreviated inner spacers 202 in FIGS. 2A-2C, as illustrated in FIGS. 3A and 3B through 8A and 8B. The features shown in FIGS. 3A and 3B through 8A and 8B that correspond to features shown in FIGS. 2A-2C are labeled as labeled in FIGS. 2A-2C.

FIGS. 3A and 3B are cross-sectional side views in a first fabrication stage 300 corresponding to the perspectives of FIGS. 2B and 2C, respectively. FIG. 3A illustrates the fabrication stage 300 in which the gates 204A and 204B are disposed on the semiconductor substrate 206. Achieving the first fabrication stage 300 includes forming the first sidewall 208A on the first side S₁ of the first gate 204A of the first transistor 205A and forming the second sidewall 208B on the second side S₂ of the second gate 204B of the second transistor 205B. The first sidewall 208A is on the first side S₁ of the first gate 204A, and the second sidewall 208B is on the second side S₂ of the second gate 204B. The oxide layer 230 is disposed between the first gate 204A and the second gate 204B. Each of the gates 204A and 204B include the dielectric cap 218 disposed on the metal gate structure 216 and an isolation layer 302 (not shown in FIGS. 2A-2C) disposed on the gates 204A and 204B and on the oxide layer 230. As shown in FIG. 3B, the source/drain region 214 in this example includes regions of the fins 232.

FIGS. 4A and 4B are cross-sectional side views in a second fabrication stage 400 in which a portion of the isolation layer 302 between the first gate 204A and the second gate 204B has been removed. In addition, the oxide layer 230 between the gates 204A and 204B has been reduced by a thickness corresponding to the height H₂₀₂ below the top 210T. The oxide layer 230 has been removed from a portion 402 of the sidewall 208 on the first side S₁ of the gate 204A and from a portion 404 of the sidewall 208 on the second side S₂ of the gate 204B. The oxide layer 230 is removed from the top 210T of the gate 204A down the first sidewall 208A to a point at which a thickness of the sidewalls 208 prevents an unacceptable leakage current to the source/drain contact 201. Where the sidewalls 208 are exposed after removal of the oxide layer 230, the sidewalls 208 may be too thin to prevent an unacceptable leakage current.

Removal of the portion of the isolation layer 302 and the oxide layer 230 is limited to between the gates 204A and 204B by first applying a mask layer (etch stop layer). The oxide layer 230 may then be reduced in height by, for example, a timed etch process that removes the oxide layer 230 at a known rate. Reducing a height of the oxide layer 230 includes forming a trench 406 in the oxide layer 230 extending between (e.g., parallel to) the gates 204A and 204B. The oxide layer 230 remaining on the source/drain region 214 has a thickness corresponding to a difference between the gate height H₂₀₄ and the height H₂₀₂ of the abbreviated inner spacers 202 shown in FIGS. 2A-2C.

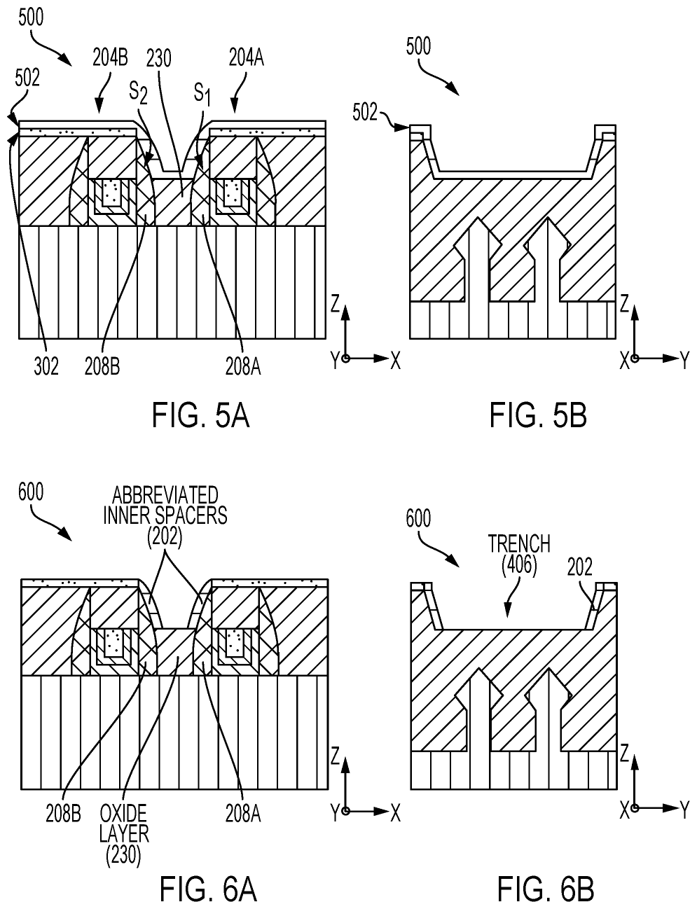

FIGS. 5A and 5B are cross-sectional side views in a third fabrication stage 500 in which an inner spacer layer 502 is disposed on the first sidewall 208A on the first side S₁ of the gate 204A and on the second sidewall 208B on the second side S₂ of the gate 204B. The inner spacer layer 502 may be a conformal layer that is also disposed (e.g., deposited) on the oxide layer 230 and on the isolation layer 302.

FIGS. 6A and 6B are cross-sectional side views in a fourth fabrication stage 600 in which the inner spacer layer 502 is thinned. Thinning the inner spacer layer 502 may include an anisotropic etching process to remove the inner spacer layer 502 from horizontal surfaces, for example. In the process of thinning the inner spacer layer 502, the inner spacer layer 502 is removed from the oxide layer 230, and the inner spacer layer 502 on top of the isolation layer 302 is also removed. On the sidewalls 208, however, a thickness of the inner spacer layer 502 on the first sidewall 208A is reduced but not entirely removed, forming a first abbreviated inner spacer 202 on the first sidewall 208A. Thinning the inner spacer layer 502 also reduces a thickness of the inner spacer layer 502 on the second sidewall 208B to form a second abbreviated inner spacer 202 on the second sidewall 208B. The processes of adding an inner spacer layer 502 and reducing a thickness of the inner spacer layer 502 also forms the abbreviated inner spacers 202 on the oxide layer 230 at both ends of the trench 406 (see FIG. 6B).

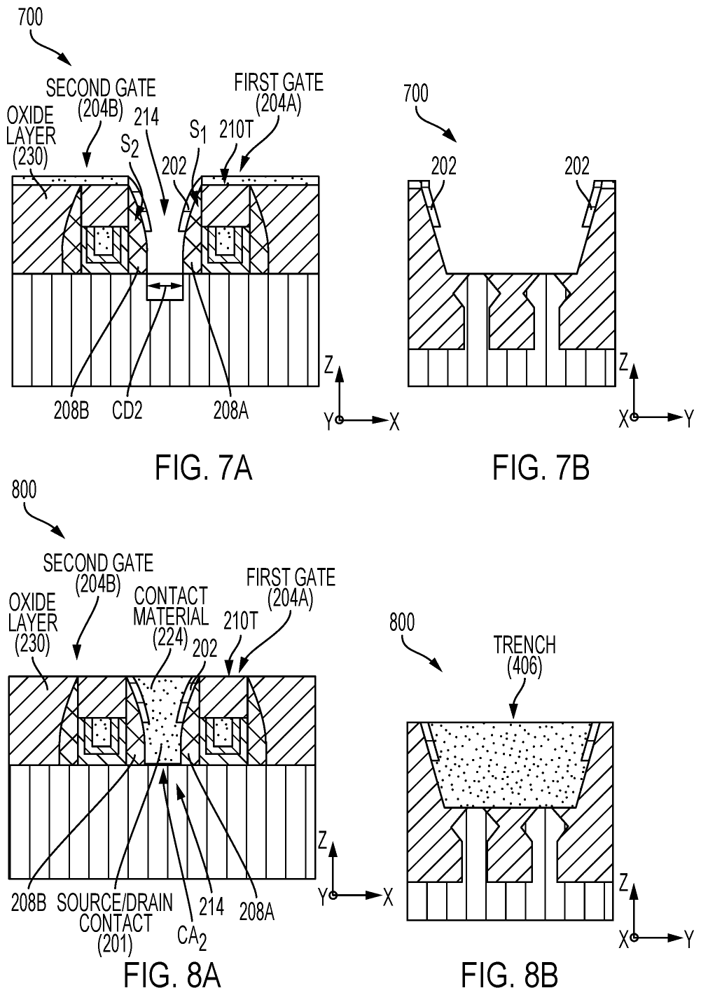

FIGS. 7A and 7B are cross-sectional side views in a fifth fabrication stage 700 in which the oxide layer 230 is removed from the source/drain region 214 between the first gate 204A and the second gate 204B. The oxide layer 230 may be removed by a self-aligned contact etch. The sidewalls 208 remain on the sides S₁ and S₂ of the gates 204A and 204B, and the abbreviated inner spacers 202 remain on the sidewalls 208. Removing the oxide layer 230 leaves the source/drain region 214 exposed from the first sidewall 208A to the second sidewall 208B, creating a space for the critical dimension CD₂ of the source/drain contact 201. The abbreviated inner spacers 202 extend down the sidewalls 208 from the top 210T.

FIGS. 8A and 8B are cross-sectional side views in a sixth fabrication stage 800 in which the contact material 224 is disposed or deposited onto the source/drain region 214 between the first and second gates 204A and 204B. The source/drain contact 201 is formed by disposing the contact material 224 on the sidewalls 208 up to the abbreviated inner spacers 202 and also on the abbreviated inner spacers 202 up to the top 210T of the gates 204A and 204B. The contact material 224 is also disposed the length of the trench 406 and onto the oxide layer 230 and the abbreviated inner spacers 202 at both ends of the trench 406. Subsequently, the fabrication stage 800 includes planarizing the source/drain contact 201 to remove the isolation layer 302 such that the source/drain contact 201 is reduced to a height of the first gate 204A and the second gate 204B. The planarizing may include a chemical mechanical polish (CMP) process.

Thus, the area CA₂ of contact between the source/drain contact 201 and the source/drain region 214 is increased by the absence of the inner spacer layers at a surface of the semiconductor substrate. The area CA₂ of contact is increased to reduce the contact resistance, which improves performance of the source/drain contact 201 over conventional methods by employing the abbreviated inner spacers 202 on the sidewalls 208 of each gate 204A and 204B.

FIG. 9 is a flowchart of the method 900 of fabricating the source/drain contact 201 and abbreviated inner spacers 202. The method includes forming a first sidewall 208A on a first side S₁ of a first gate 204A of a first transistor 205A and a second sidewall 208B on a second side S₂ of a second gate 204B of a second transistor 205B (block 902). The method includes forming a first abbreviated inner spacer 202 on the first sidewall 208A and a second abbreviated inner spacer 202 on the second sidewall 208B (block 904). The method also includes forming a source/drain contact 201 on a source/drain region 214 of the first and second transistors (205A, 205B) between the first gate 204A and the second gate 204B, the source/drain contact 201 extending from the first sidewall 208A to the second sidewall 208B (block 906).

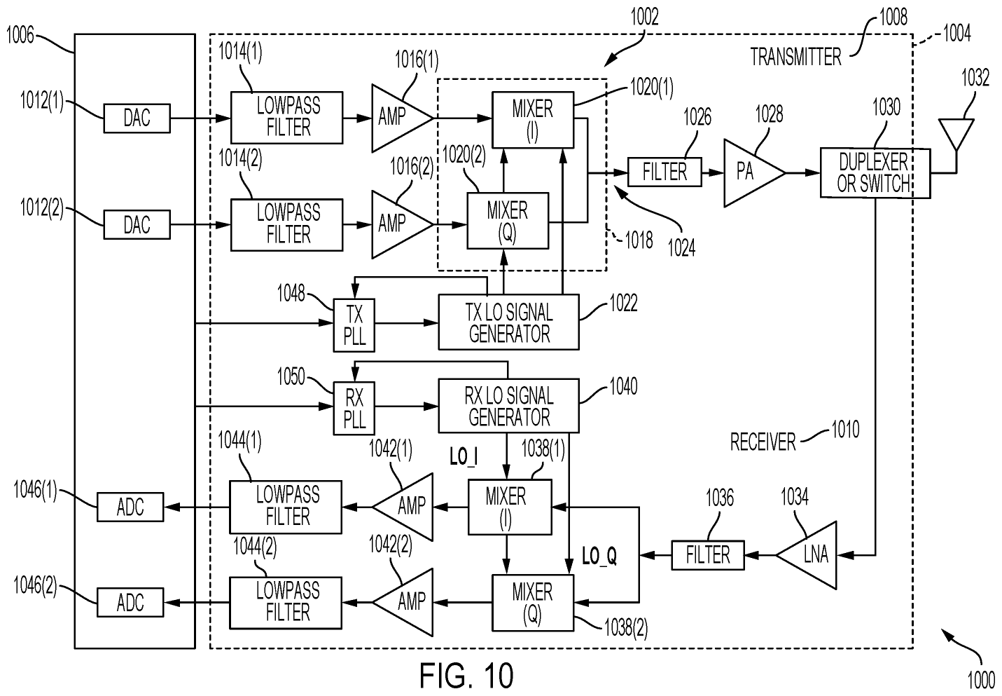

FIG. 10 illustrates an exemplary wireless communications device 1000 that includes radio frequency (RF) components formed from one or more integrated circuits (ICs) 1002, wherein any of the ICs 1002 can include exemplary abbreviated inner spacers on sidewalls on a first gate of a first transistor and a second gate of a second transistor and a source/drain contact disposed between the gates and having an extended critical dimension from sidewall to sidewall for reduced contact resistance, as illustrated in any of FIGS. 2A-2C and 8A-8B, and according to any of the aspects disclosed herein. As shown in FIG. 10, the wireless communications device 1000 includes a transceiver 1004 and a data processor 1006. The data processor 1006 may include a memory to store data and program codes. The transceiver 1004 includes a transmitter 1008 and a receiver 1010 that support bi-directional communications. In general, the wireless communications device 1000 may include any number of transmitters 1008 and/or receivers 1010 for any number of communication systems and frequency bands. All or a portion of the transceiver 1004 may be implemented on one or more analog ICs, RFICs, mixed-signal ICs, etc.

The transmitter 1008 or the receiver 1010 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage. In the direct-conversion architecture, a signal is frequency-converted between RF and baseband in one stage. The super-heterodyne and direct-conversion architectures may use different circuit blocks and/or have different requirements. In the wireless communications device 1000 in FIG. 10, the transmitter 1008 and the receiver 1010 are implemented with the direct-conversion architecture.

In the transmit path, the data processor 1006 processes data to be transmitted and provides I and Q analog output signals to the transmitter 1008. In the exemplary wireless communications device 1000, the data processor 1006 includes digital-to-analog converters (DACs) 1012(1), 1012(2) for converting digital signals generated by the data processor 1006 into the I and Q analog output signals, e.g., I and Q output currents, for further processing.

Within the transmitter 1008, lowpass filters 1014(1), 1014(2) filter the I and Q analog output signals, respectively, to remove undesired signals caused by the prior digital-to-analog conversion. Amplifiers (AMPs) 1016(1), 1016(2) amplify the signals from the lowpass filters 1014(1), 1014(2), respectively, and provide I and Q baseband signals. An upconverter 1018 upconverts the I and Q baseband signals with I and Q transmit (TX) local oscillator (LO) signals from a TX LO signal generator 1022 through mixers 1020(1), 1020(2) to provide an upconverted signal 1024. A filter 1026 filters the upconverted signal 1024 to remove undesired signals caused by the frequency upconversion as well as noise in a receive frequency band. A power amplifier (PA) 1028 amplifies the upconverted signal 1024 from the filter 1026 to obtain the desired output power level and provides a transmit RF signal. The transmit RF signal is routed through a duplexer or switch 1030 and transmitted via an antenna 1032.

In the receive path, the antenna 1032 receives signals transmitted by base stations and provides a received RF signal, which is routed through the duplexer or switch 1030 and provided to a low noise amplifier (LNA) 1034. The duplexer or switch 1030 is designed to operate with a specific receive (RX)-to-TX duplexer frequency separation, such that RX signals are isolated from TX signals. The received RF signal is amplified by the LNA 1034 and filtered by a filter 1036 to obtain a desired RF input signal. Downconversion mixers 1038(1), 1038(2) mix the output of the filter 1036 with I and Q RX LO signals (i.e., LO_I and LO_Q) from an RX LO signal generator 1040 to generate I and Q baseband signals. The I and Q baseband signals are amplified by AMPs 1042(1), 1042(2) and further filtered by lowpass filters 1044(1), 1044(2) to obtain I and Q analog input signals, which are provided to the data processor 1006. In this example, the data processor 1006 includes analog-to-digital converters (ADCs) 1046(1), 1046(2) for converting the analog input signals into digital signals to be further processed by the data processor 1006.

In the wireless communications device 1000 of FIG. 10, the TX LO signal generator 1022 generates the I and Q TX LO signals used for frequency upconversion, while the RX LO signal generator 1040 generates the I and Q RX LO signals used for frequency downconversion. Each LO signal is a periodic signal with a particular fundamental frequency. A TX phase-locked loop (PLL) circuit 1048 receives timing information from the data processor 1006 and generates a control signal used to adjust the frequency and/or phase of the TX LO signals from the TX LO signal generator 1022. Similarly, an RX PLL circuit 1050 receives timing information from the data processor 1006 and generates a control signal used to adjust the frequency and/or phase of the RX LO signals from the RX LO signal generator 1040.

Wireless communications devices 1000 that each include exemplary abbreviated inner spacers on sidewalls on a first gate of a first transistor and a second gate of a second transistor and a source/drain contact disposed between the gates and having an extended critical dimension from sidewall to sidewall for reduced contact resistance, as illustrated in any of FIGS. 2A-2C and 8A-8B, and according to any of the aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

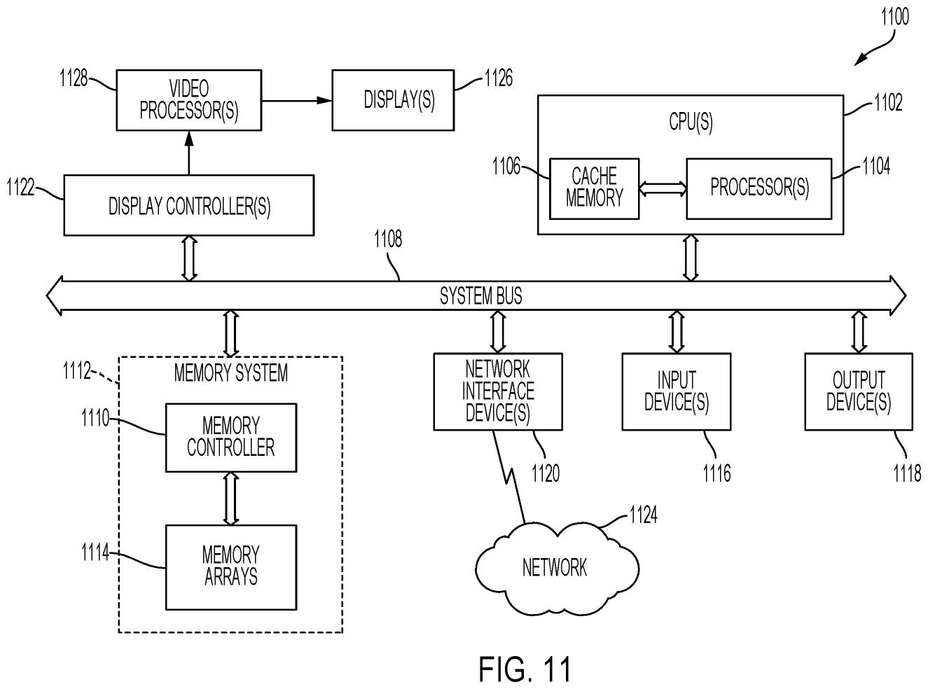

In this regard, FIG. 11 illustrates an example of a processor-based system 1100 including ICs including exemplary abbreviated inner spacers on sidewalls on a first gate of a first transistor and a second gate of a second transistor and a source/drain contact disposed between the gates and having an extended critical dimension from sidewall to sidewall for reduced contact resistance, as illustrated in any of FIGS. 2A-2C and 8A-8B, and according to any aspects disclosed herein. In this example, the processor-based system 1100 includes one or more central processor units (CPUs) 1102, which may also be referred to as CPU or processor cores, each including one or more processors 1104. The CPU(s) 1102 may have cache memory 1106 coupled to the processor(s) 1104 for rapid access to temporarily stored data. As an example, the processor(s) 1104 could include exemplary abbreviated inner spacers on sidewalls on a first gate of a first transistor and a second gate of a second transistor and a source/drain contact disposed between the gates and having an extended critical dimension from sidewall to sidewall for reduced contact resistance, as illustrated in any of FIGS. 2A-2C and 8A-8B, and according to any aspects disclosed herein. The CPU(s) 1102 is coupled to a system bus 1108 and can intercouple master and slave devices included in the processor-based system 1100. As is well known, the CPU(s) 1102 communicates with these other devices by exchanging address, control, and data information over the system bus 1108. For example, the CPU(s) 1102 can communicate bus transaction requests to a memory controller 1110 as an example of a slave device. Although not illustrated in FIG. 11, multiple system buses 1108 could be provided, wherein each system bus 1108 constitutes a different fabric.

Other master and slave devices can be connected to the system bus 1108. As illustrated in FIG. 11, these devices can include a memory system 1112 that includes the memory controller 1110 and one or more memory arrays 1114, one or more input devices 1116, one or more output devices 1118, one or more network interface devices 1120, and one or more display controllers 1122, as examples. Each of the memory system 1112, the one or more input devices 1116, the one or more output devices 1118, the one or more network interface devices 1120, and the one or more display controllers 1122 can include exemplary abbreviated inner spacers on sidewalls on a first gate of a first transistor and a second gate of a second transistor and a source/drain contact disposed between the gates and having an extended critical dimension from sidewall to sidewall for reduced contact resistance, as illustrated in any of FIGS. 2A-2C and 8A-8B, and according to any of the aspects disclosed herein. The input device(s) 1116 can include any type of input device, including, but not limited to, input keys, switches, voice processors, etc. The output device(s) 1118 can include any type of output device, including, but not limited to, audio, video, other visual indicators, etc. The network interface device(s) 1120 can be any device configured to allow exchange of data to and from a network 1124. The network 1124 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1120 can be configured to support any type of communications protocol desired.

The CPU(s) 1102 may also be configured to access the display controller(s) 1122 over the system bus 1108 to control information sent to one or more displays 1126. The display controller(s) 1122 sends information to the display(s) 1126 to be displayed via one or more video processors 1128, which process the information to be displayed into a format suitable for the display(s) 1126. The display(s) 1126 can include any type of display, including, but not limited to, a cathode ray tube (CRT), a liquid crystal display (LCD), a plasma display, a light emitting diode (LED) display, etc. The display controller(s) 1122, display(s) 1126, and/or the video processor(s) 1128 can include exemplary abbreviated inner spacers on sidewalls on a first gate of a first transistor and a second gate of a second transistor and a source/drain contact disposed between the gates and having an extended critical dimension from sidewall to sidewall for reduced contact resistance, as illustrated in any of FIGS. 2A-2C and 8A-8B, and according to any of the aspects disclosed herein.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. The master and slave devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

Implementation examples are described in the following numbered clauses:

1. An Integrated Circuit (IC) Comprising:
a first transistor on a semiconductor substrate, the first transistor comprising a first gate on a first channel region, the first gate comprising a top and a first side;
a second transistor on the semiconductor substrate, the second transistor comprising a second gate on a second channel region, the second gate comprising a top and a second side;
a source/drain region between the first gate and the second gate;
a first sidewall disposed on the first side of the first gate;
a second sidewall disposed on the second side of the second gate;
a first inner spacer disposed on the first sidewall;
a second inner spacer disposed on the second sidewall; and
a source/drain contact disposed on the source/drain region, the source/drain contact in direct contact with the first inner spacer, the second inner spacer, the first sidewall, and the second sidewall.

2. The IC of clause 1, wherein:
the first side comprises a gate height from the top of the first gate to the semiconductor substrate;
the second side comprises the gate height from the top of the second gate to the semiconductor substrate;
the first sidewall extends the gate height on the first side of the first gate;
the second sidewall extends the gate height on the second side of the second gate;
the first inner spacer comprises a first height less than the gate height from the top of the first gate on the first sidewall; and
the second inner spacer comprises the first height from the top of the second gate on the second sidewall.

3. The IC of clause 2, wherein:
the first height of the first inner spacer in a direction from the top of the first gate to the semiconductor substrate is between 35% and 65% of the gate height; and
the first height of the second inner spacer in the direction from the top of the first gate to the semiconductor substrate is between 35% and 65% of the gate height.

4. The IC of any one of clauses 1 to 3, wherein:
the source/drain contact is in direct contact with the first sidewall between the first inner spacer and the semiconductor substrate; and
the source/drain contact is in direct contact with the second sidewall between the second inner spacer and the semiconductor substrate.

5. The IC of clause 2 or clause 3, wherein:
each of the first gate and the second gate comprises:
   a metal gate structure comprising a top of the metal gate structure; and
   a dielectric cap disposed on the top of the metal gate structure, the dielectric cap comprising a second height from a top of the dielectric cap to the top of the metal gate structure, wherein the top of the dielectric cap comprises the top of each gate; and
each of the first inner spacer and the second inner spacer comprises a top edge and a bottom edge, and the first height comprises a distance from the top edge to the bottom edge greater than or equal to the second height.

6. The IC of clause 5, wherein the bottom edge of each of the first inner spacer and the second inner spacer is disposed between the top of the metal gate structure and the semiconductor substrate.

7. The IC of clause 5 or clause 6, wherein:
the source/drain contact is in direct contact with the first sidewall from the bottom edge of the first inner spacer to the semiconductor substrate; and
the source/drain contact is in direct contact with the second sidewall from the bottom edge of the second inner spacer to the semiconductor substrate.

8. The IC of any one of clauses 5 to 7, wherein:
the source/drain contact is disposed on the first inner spacer from the bottom edge to the top edge of the first inner spacer; and
the source/drain contact is disposed on the second inner spacer from the bottom edge to the top edge of the second inner spacer.

9. The IC of clause any one of clauses 1 to 8, wherein the semiconductor substrate comprises a fin.

10. The IC of any one of clauses 1 to 9, wherein the first inner spacer and the second inner spacer comprise silicon nitride (SiN).

11. The IC of any one of clauses 1 to 10, integrated into a radio-frequency (RF) front end module.

12. The IC of any one of clauses 1 to 11 integrated into a device selected from the group consisting of a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

13. A method of fabricating a source/drain contact, the method comprising:
forming a first sidewall on a first side of a first gate of a first transistor and a second sidewall on a second side of a second gate of a second transistor;
forming a first inner spacer on the first sidewall and a second inner spacer on the second sidewall; and
forming a source/drain contact on a source/drain region of the first transistor and the second transistor between the first gate and the second gate, the source/drain contact in direct contact with the first inner spacer, the second inner spacer, the first sidewall, and the second sidewall.

14. The method of clause 13, wherein forming the first inner spacer on the first sidewall and the second inner spacer on the second sidewall further comprises reducing, by a first height, a thickness of an oxide layer between the first sidewall and the second sidewall.

15. The method of clause 14, further comprising disposing an inner spacer layer on the first sidewall, the second sidewall, and the oxide layer.

16. The method of clause 15, further comprising etching the inner spacer layer comprising:
removing the inner spacer layer from the oxide layer; and
reducing a thickness of the inner spacer layer on the first sidewall to form the first inner spacer and on the second sidewall to form the second inner spacer.

17. The method of clause 16, wherein.
reducing the thickness of the oxide layer between the first sidewall and the second sidewall further comprises forming a trench in the oxide layer; and
disposing an inner spacer layer on the first sidewall, the second sidewall, and the oxide layer further comprises disposing the inner spacer layer on the oxide layer at ends of the trench.

18. The method of clause 17, further comprising:
disposing a contact material of the source/drain contact on the source/drain region extending from the first sidewall to the second sidewall; and
polishing a top of the source/drain contact.

19. The method of clause 18, wherein disposing the contact material comprises disposing the contact material on the first inner spacer, the first sidewall, the second sidewall, and the second inner spacer.

What is claimed is:

1. An integrated circuit (IC) comprising:
a first transistor on a semiconductor substrate, the first transistor comprising a first gate on a first channel region, the first gate comprising a top and
a first side;
a second transistor on the semiconductor substrate, the second transistor comprising a second gate on a second channel region, the second gate comprising a top and a second side;
a source/drain region between the first gate and the second gate;
a first sidewall disposed on the first side of the first gate;
a second sidewall disposed on the second side of the second gate;
a first inner spacer disposed on the first sidewall;
a second inner spacer disposed on the second sidewall; and
a source/drain contact disposed on the source/drain region, the source/drain contact in direct contact with the first inner spacer, the second inner spacer, the first sidewall, and the second sidewall.

2. The IC of claim 1, wherein:
the first side comprises a gate height from the top of the first gate to the semiconductor substrate;
the second side comprises the gate height from the top of the second gate to the semiconductor substrate;
the first sidewall extends the gate height on the first side of the first gate;
the second sidewall extends the gate height on the second side of the second gate;
the first inner spacer comprises a first height less than the gate height from the top of the first gate on the first sidewall; and
the second inner spacer comprises the first height from the top of the second gate on the second sidewall.

3. The IC of claim 2, wherein:
the first height of the first inner spacer in a direction from the top of the first gate to the semiconductor substrate is between 35% and 65% of the gate height; and
the first height of the second inner spacer in the direction from the top of the first gate to the semiconductor substrate is between 35% and 65% of the gate height.

4. The IC of claim 1, wherein:
the source/drain contact is in direct contact with the first sidewall between the first inner spacer and the semiconductor substrate; and
the source/drain contact is in direct contact with the second sidewall between the second inner spacer and the semiconductor substrate.

5. The IC of claim 2, wherein:
each of the first gate and the second gate comprises:
a metal gate structure comprising a top of the metal gate structure; and
a dielectric cap disposed on the top of the metal gate structure, the dielectric cap comprising a second height from a top of the dielectric cap to the top of the metal gate structure, wherein the top of the dielectric cap comprises the top of each gate; and
each of the first inner spacer and the second inner spacer comprises a top edge and a bottom edge, and the first height comprises a distance from the top edge to the bottom edge greater than or equal to the second height.

6. The IC of claim 5, wherein the bottom edge of each of the first inner spacer and the second inner spacer is disposed between the top of the metal gate structure and the semiconductor substrate.

7. The IC of claim 5, wherein:
the source/drain contact is in direct contact with the first sidewall from the bottom edge of the first inner spacer to the semiconductor substrate; and
the source/drain contact is in direct contact with the second sidewall from the bottom edge of the second inner spacer to the semiconductor substrate.

8. The IC of claim 5, wherein:
the source/drain contact is disposed on the first inner spacer from the bottom edge to the top edge of the first inner spacer; and
the source/drain contact is disposed on the second inner spacer from the bottom edge to the top edge of the second inner spacer.

9. The IC of claim 1, wherein the semiconductor substrate comprises a fin.

10. The IC of claim 1, wherein the first inner spacer and the second inner spacer comprise silicon nitride (SiN).

11. The IC of claim 1, integrated into a radio-frequency (RF) front end module.

12. The IC of claim 1 integrated into a device selected from the group consisting of a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

13. A method of fabricating a source/drain contact, the method comprising:
forming a first sidewall on a first side of a first gate of a first transistor and a second sidewall on a second side of a second gate of a second transistor;
forming a first inner spacer on the first sidewall and a second inner spacer on the second sidewall; and
forming a source/drain contact on a source/drain region of the first transistor and the second transistor between the first gate and the second gate, the source/drain contact in direct contact with the first inner spacer, the second inner spacer, the first sidewall, and the second sidewall.

14. The method of claim 13, wherein forming the first inner spacer on the first sidewall and the second inner spacer on the second sidewall further comprises reducing, by a first height, a thickness of an oxide layer between the first sidewall and the second sidewall.

15. The method of claim 14, further comprising disposing an inner spacer layer on the first sidewall, the second sidewall, and the oxide layer.

16. The method of claim 15, further comprising etching the inner spacer layer comprising:
removing the inner spacer layer from the oxide layer; and
reducing a thickness of the inner spacer layer on the first sidewall to form the first inner spacer and on the second sidewall to form the second inner spacer.

17. The method of claim 16, wherein:
reducing the thickness of the oxide layer between the first sidewall and the second sidewall further comprises forming a trench in the oxide layer; and
disposing an inner spacer layer on the first sidewall, the second sidewall, and the oxide layer further comprises disposing the inner spacer layer on the oxide layer at ends of the trench.

18. The method of claim 17, further comprising:
disposing a contact material of the source/drain contact on the source/drain region extending from the first sidewall to the second sidewall; and
polishing a top of the source/drain contact.

19. The method of claim 18, wherein disposing the contact material comprises disposing the contact material on the first inner spacer, the first sidewall, the second sidewall, and the second inner spacer.
